(19) United States
(12) Patent Application Publication
(10) Pub. No.: US 2025/0268011 A1
(43) Pub. Date: Aug. 21, 2025

(54) LIGHT-EMITTING UNIT AND LIGHT-EMITTING DEVICE

(71) Applicant: LITE-ON TECHNOLOGY CORPORATION, TAIPEI CITY (TW)

(72) Inventors: HONG-YE LAI, Taichung City (TW); MIAO-SAN CHIEN, Hsinchu County (TW); SHENG-YUN WANG, New Taipei City (TW); Kai-Chieh Liang, New Taipei City (TW)

(21) Appl. No.: 19/009,605

(22) Filed: Jan. 3, 2025

Related U.S. Application Data
(60) Provisional application No. 63/555,988, filed on Feb. 21, 2024.

(30) Foreign Application Priority Data
Dec. 20, 2024 (CN) 202423167021.0

(51) Int. Cl. H10H 29/853; H01L 25/075; H10H 29/80; H10H 29/85

(52) U.S. Cl. CPC H10H 29/853; H01L 25/0753; H10H 29/8506; H10H 29/857; H10H 29/942

(57) ABSTRACT

A light-emitting unit and a light-emitting device are provided. The light-emitting unit includes a light-emitting chip and an optical encapsulant. The light-emitting unit has a top surface and a bottom surface opposite to each other in the thickness direction, and a surrounding side surface. The top surface and the bottom surface are surrounded by the surrounding side surface, and the light-emitting chip includes a connection pad located on the bottom surface and a wire bonding point that is located on the top surface. The surrounding side surface of the light-emitting chip is surrounded by the optical encapsulant, and the top surface and the bottom surface of the light-emitting chip are exposed outside of the optical encapsulant.

### CROSS-REFERENCE TO RELATED PATENT APPLICATION

This application claims the benefit of priorities to the U.S. Provisional Patent Application Ser. No. 63/555,988, filed on Feb. 21, 2024, and China Patent Application No. 202423167021.0, filed on Dec. 20, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device, and more particularly to a light-emitting unit and a light-emitting device.

### BACKGROUND OF THE DISCLOSURE

Currently, the LED industry is introducing Chip Scale Package (CSP) into various light-emitting devices. Among these, conventional CSPs often use flip-chip technology and encapsulate five sides of the flip chip. However, vertical chips have better light extraction efficiency compared to flip chips, but are limited by the wire bonding position, making application to the conventional CSP manufacturing process for flip chips impossible. In other words, the industry currently lacks a solution to manufacture vertical chips in CSP form and flexibly apply vertical chips to light-emitting devices.

### SUMMARY OF THE DISCLOSURE

In response to the above-referenced technical inadequacy, the present disclosure provides a light-emitting unit and a light-emitting device.

In order to solve the above-mentioned problems, one of the technical aspects adopted by the present disclosure is to provide a light-emitting unit. The light-emitting unit includes a light-emitting chip and an optical encapsulant. The light-emitting chip has a top surface and a bottom surface opposite to each other in a thickness direction, and a surrounding side surface. The top surface and the bottom surface are surrounded by the surrounding side surface, and the light-emitting chip includes a connection pad located on the bottom surface and a wire bonding point that is located on the top surface. The surrounding side surface of the light-emitting chip is surrounded by the optical encapsulant, and the top surface and the bottom surface of the light-emitting chip are exposed outside of the optical encapsulant.

In order to solve the above-mentioned problems, another one of the technical aspects adopted by the present disclosure is to provide a light-emitting device. The light-emitting device includes the above-mentioned light-emitting unit, a substrate, and a packaging encapsulant. The substrate includes a first circuit and a second circuit. The light-emitting unit is disposed on the substrate. The packaging encapsulant is disposed on the substrate. The light-emitting unit is covered by the packaging encapsulant. The light-emitting chip is die-bonded to the first circuit through the connection pad, the wire bonding point is connected to the second circuit through a conductive wire of the light-emitting device, and the conductive wire is exposed outside of the optical encapsulant.

Therefore, in the light-emitting unit and the light-emitting device. provided by the present disclosure, by virtue of “the surrounding side surface of the light-emitting chip being surrounded by the optical encapsulant, and the top surface and the bottom surface of the light-emitting chip being exposed outside of the optical encapsulant,” the light-emitting unit and light-emitting device can improve yield and light emission performance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic planar view of a light-emitting unit according to one embodiment of the present disclosure;

FIG. 2 is a schematic planar view of a light-emitting device according to one embodiment of the present disclosure;

FIG. 3 is a flowchart of a manufacturing method of the light-emitting unit according to one embodiment of the present disclosure;

FIG. 4 is a schematic planar view of a light-emitting chip about to be disposed on a cushion layer according to one embodiment of the present disclosure;

FIG. 5 is a schematic planar view of a portion of the light-emitting chip embedded in the cushion layer according to one embodiment of the present disclosure;

FIG. 6 is a schematic planar view of an optical encapsulant filled between the light-emitting chips according to one embodiment of the present disclosure;

FIG. 7 is a schematic planar view of the optical encapsulant being cut according to one embodiment of the present disclosure;

FIG. 8 is a flowchart of a manufacturing method of the light-emitting device according to one embodiment of the present disclosure;

FIG. 9 is a schematic planar view of a substrate being unprocessed according to one embodiment of the present disclosure;

FIG. 10 is a schematic planar view of the light-emitting unit disposed on the substrate according to one embodiment of the present disclosure;

FIG. 11 is a schematic planar view of the light-emitting unit covered by a packaging encapsulant according to one embodiment of the present disclosure;

FIG. 12 is a schematic planar view of the packaging encapsulant and a portion of the substrate being cut according to one embodiment of the present disclosure;

FIG. 13 is a schematic planar view of the packaging encapsulant covered by an opaque encapsulant according to one embodiment of the present disclosure;

FIG. 14 is a schematic planar view of the opaque encapsulant after being processed according to one embodiment of the present disclosure;

FIG. 15 is a schematic planar view of the opaque encapsulant and the substrate being cut according to one embodiment of the present disclosure;

FIG. 16 is a schematic planar view of the light-emitting device according to another embodiment of the present disclosure; and

FIG. 17 is a schematic top view of the light-emitting device according to yet another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

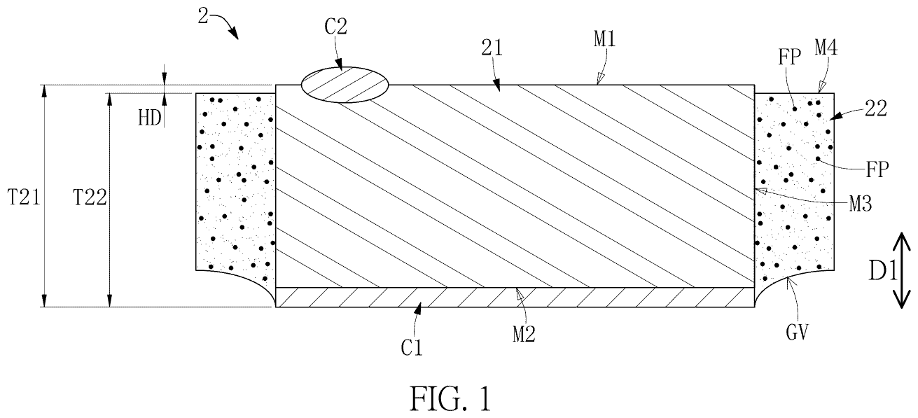

Referring to FIG. 1, the present disclosure provides a light-emitting unit 2 including a light-emitting chip 21 and an optical encapsulant 22. The following description describes the structure and connection relation of each component of the light-emitting unit 2.

Specifically, the light-emitting chip 21 has a thickness direction D1, and the light-emitting chip 21 has a top surface M1 and a bottom surface M2 opposite to each other in the thickness direction D1, and a surrounding side surface M3 that is connected to the top surface M1 and the bottom surface M2. The top surface M1 and the bottom surface M2 are surrounded by the surrounding side surface M3. The light-emitting chip 21 includes a connection pad C1 located on the bottom surface M2 and a wire bonding point C2 that is located on the top surface M1.

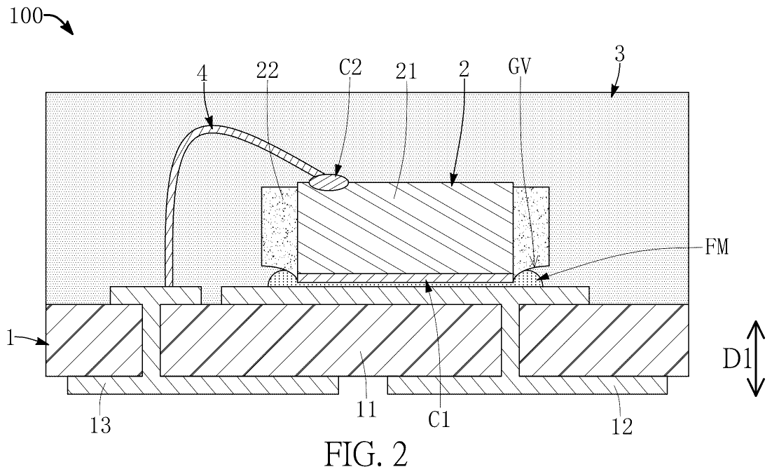

Through the above structure, the light-emitting chip 21 can be die-bonded to one circuit of a substrate (for example, the first circuit 12 of the substrate 1 in FIG. 2 described later) via the connection pad C1, and the wire bonding point C2 can be connected to another circuit of the substrate (for example, the second circuit 13 of the substrate 1 in FIG. 2 described later) via a conductive wire, so that the light-emitting chip 21 can be electrically coupled to the substrate 1.

Referring to FIG. 1, the surrounding side surface M3 of the light-emitting chip 21 is surrounded by the optical encapsulant 22, and the top surface M1 and the bottom surface M2 of the light-emitting chip 21 are exposed outside of the optical encapsulant 22. In other words, a light-emitting surface (i.e., the top surface M1) of the light-emitting chip 21 will not be covered by the optical encapsulant 22, so that a light output amount will not be affected by being covered by the optical encapsulant 22.

It is worth noting that, in the present embodiment, the optical encapsulant 22 further includes a plurality of functional particles FP, and the functional particles FP can include at least one of light-reflecting particles, light-absorbing particles, coloring particles, light-diffusing particles, and fluorescent particles. In one embodiment, the functional particles FP can be the light-reflecting particles as an example. The light output efficiency of the light-emitting unit 2 in the present embodiment can be effectively improved, and the light output angle can be effectively controlled.

Preferably, a portion of the optical encapsulant 22 adjacent to the connection pad C1 has a groove GV. Accordingly, as shown in FIG. 2 described later, the groove GV can be used to accommodate the die bonding material FM that is excess, so as to increase the adhesion between the chip and the substrate. Simultaneously, the groove GV can reduce an occurrence of the die bonding material FM extending to a side of the optical encapsulant 22, so as to avoid effects on the product appearance and optical effects (such as reflection or light diffusion effects). Moreover, an unfilled region of the groove GV not filled by the die bonding material FM can also be filled with a precursor of a packaging encapsulant (for example, the packaging encapsulant 3 in FIG. 2), so that the packaging encapsulant that is cured can fill the groove GV together with the optical encapsulant and create a geometric match. Accordingly, a connection reliability between the light-emitting unit 2 and the packaging encapsulant can be effectively improved.

Referring again to FIG. 1, in subsequent applications in terminal products (for example, the light-emitting device 100 in FIG. 2), to ensure that the wire bonding point C2 on the top surface of the light-emitting chip 21 is exposed to the optical encapsulant 22, a cross-section of the light-emitting unit 2 along the thickness direction D1 can preferably be designed in a “higher in the middle and lower on both sides” stepped shape, so that the light-emitting chip 21 surrounded by the optical encapsulant 22 can protrude further above the optical encapsulant 22.

Specifically, the top surface M1 of the light-emitting chip 21 (relative to the substrate 1) has a first height position, the optical encapsulant 22 includes a platform surface M4 (away from the substrate 1), and the platform surface M4 has a second height position relative to the substrate 1. The second height position is lower than the first height position, so that a portion of the surrounding side surface M3 adjacent to the top surface is exposed outside of the optical encapsulant 22. Accordingly, the optical encapsulant 22 can avoid covering the wire bonding point C2 and the top surface M1, so as to prevent impacts on the wire bonding space and light output performance.

Preferably, a height difference HD between the first height position and the second height position is less than 50% of the thickness of the light-emitting chip 21 along the thickness direction D1 (i.e., a first minimum thickness T21). More preferably, the height difference is within a range from 10micrometers to 15 micrometers.

In other words, the light-emitting chip 21 has a first minimum thickness T21 along the thickness direction D1, the optical encapsulant 22 has a second minimum thickness T22 along the thickness direction D1, and the first minimum thickness T21 is greater than the second minimum thickness T22.

In a preferred embodiment, the second minimum thickness T22 can be within a range from 75% to 85% of the first minimum thickness T21 (that is, the height difference is within a range from 15% to 25% of the thickness of the light-emitting chip 21), so as to provide a more complete optical effect (such as reflection effects) and also provide the optical encapsulant 22 from dispersing to the wire bonding point C2. Additionally, a width of the platform surface M4 of the optical encapsulant 22 is preferably greater than or equal to 30 micrometers, so as to ensure that the width of the optical encapsulant 22 can provide an ideal optical effect (such as reflection effects).

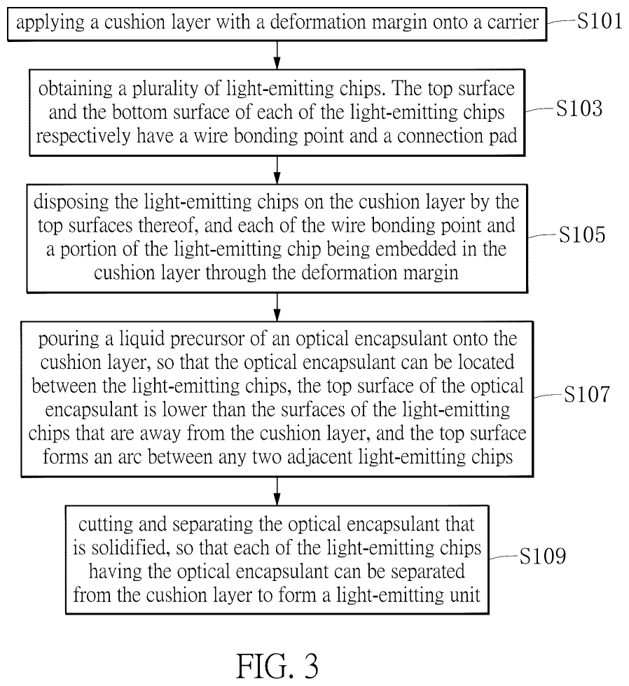

The above describes the structure of the light-emitting unit 2 of the present disclosure. However, for a better understanding of the light-emitting unit 2 of the present disclosure, the following introduces the manufacturing process of the light-emitting unit 2 in one of the embodiments. The manufacturing method for the light-emitting unit 2 includes steps S101 to S109 (as shown in FIG. 3).

### Manufacturing Method of the Light-Emitting Unit 2

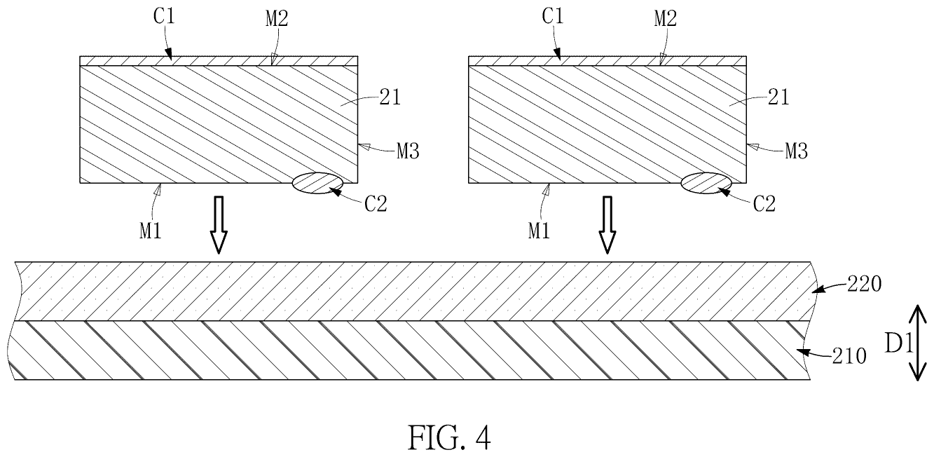

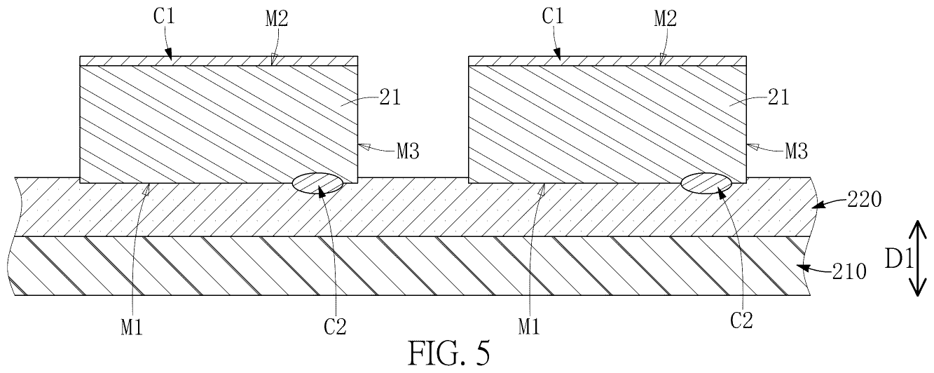

Steps S101 to S105 should be referred to in conjunction with FIG. 4 and FIG. 5.

The step S101 is implemented by applying a cushion layer 220 (e.g., cushioning tape) with a deformation margin onto a carrier 210 (e.g., a steel plate).

The step S103 is implemented by obtaining a plurality of light-emitting chips 21. The top surface M1 and the bottom surface M2 of each of the light-emitting chips 21 respectively have a wire bonding point C2 and a connection pad C1.

The step S105 is implemented by disposing the light-emitting chips 21 on the cushion layer 220 by the top surfaces M1 thereof, and each of the wire bonding point C2 and a portion of the light-emitting chip 21 being embedded in the cushion layer 220 through the deformation margin.

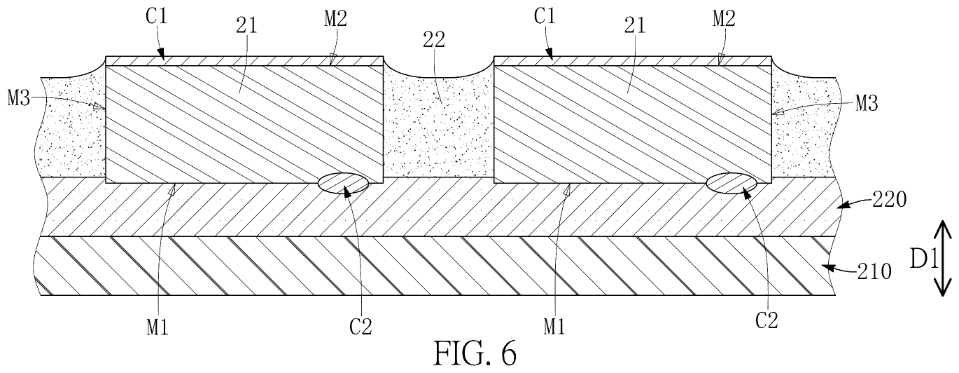

The step S107 is implemented by pouring a liquid precursor of an optical encapsulant 22 onto the cushion layer 220 and solidifying it (as shown in FIG. 6), so that the optical encapsulant 22 can be located between the light-emitting chips 21, the top surface of the optical encapsulant 22 is lower than the surfaces of the light-emitting chips 21 that are away from the cushion layer 220, and the top surface forms an arc between any two adjacent light-emitting chips 21.

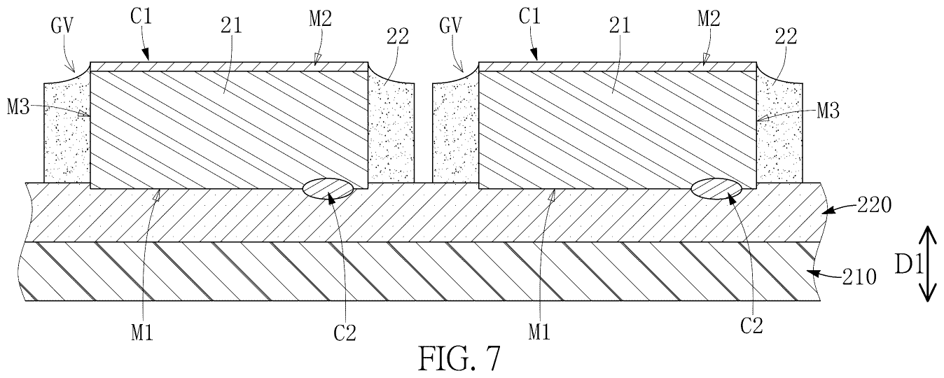

The step S109 is implemented by cutting and separating the optical encapsulant 22 that is solidified (as shown in FIG. 7), so that each of the light-emitting chips having the optical encapsulant 2221 can be separated from the cushion layer 220 to form a light-emitting unit 2 (as shown in FIG. 1). In other words, the top surface M1 and the bottom surface M2 of the light-emitting chip 21 are exposed, and the surrounding side surface M3 of the light-emitting chip 21 is surrounded by the optical encapsulant 22.

Next, a light-emitting device 100 provided in the present disclosure is introduced. Referring to FIG. 2, the light-emitting device 100 includes a substrate 1, the light-emitting unit 2 disposed on the substrate 1, a packaging encapsulant 3 disposed on the substrate 1 and covering the light-emitting unit 2, and a conductive wire 4 that is connected to the substrate 1 and the light-emitting unit 2.

Referring to FIG. 1 and FIG. 2, the light-emitting unit 2 can be electrically coupled to the substrate 1 through the first circuit 12 and the second circuit 13. Specifically, the light-emitting chip 21 is die-bonded to the first circuit 12 via the connection pad C1, and the wire bonding point C2 is connected to the second circuit 13 via the conductive wire 4, so that the light-emitting chip 21 can be electrically coupled to the substrate 1. The packaging encapsulant 3 is disposed on the substrate 1, and the light-emitting unit 2 and the conductive wire 4 are covered by the packaging encapsulant 3, so as to protect the light-emitting unit 2 and the conductive wire 4.

The precursor of the packaging encapsulant 3 can be filled into the groove GV before solidifying, and the optical encapsulant 22 can also be indirectly fixed onto the substrate 1 by the packaging encapsulant 3 that is solidified. Furthermore, the conductive wire 4 is covered only by the packaging encapsulant 3 and not by the optical encapsulant 22. As a result, the conductive wire 4 experiences only a single stress from the packaging encapsulant 3, so as to prevent the occurrence of damage due to pulling on the conductive wire 4.

In practice, the packaging encapsulant 3 may include fluorescent particles or light-diffusing particles, and the composition of the packaging encapsulant 3 is different from the composition of the optical encapsulant 22. In other words, the conductive wire 4 is not covered by two different materials.

Naturally, the composition of the optical encapsulant 22 and the packaging encapsulant 3 can also be the same depending on the requirement, such as being epoxy-based resin or silicone-based resin.

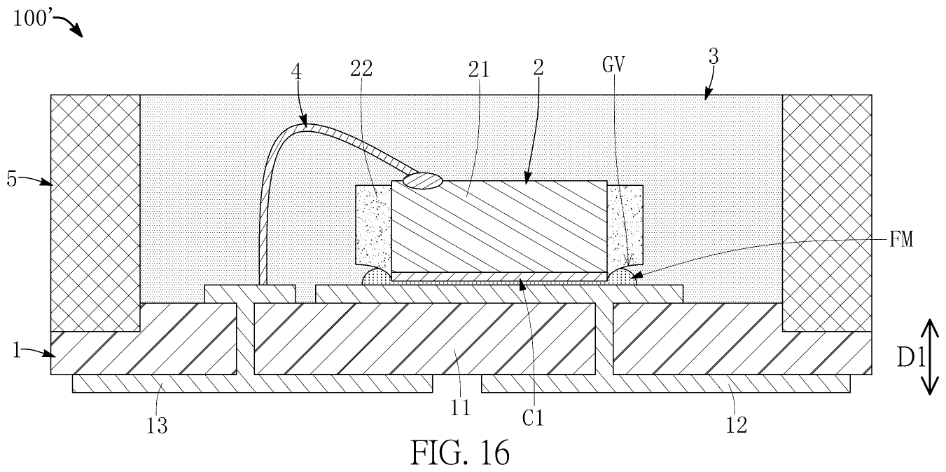

It should be additionally noted that, as shown in FIG. 16, the light-emitting device 100′ may optionally include an additional wall 5 on the substrate 1 in practical applications. Preferably, the wall 5 can have reflective or light-absorbing properties. In one embodiment, the wall 5 surrounds and contacts the packaging encapsulant 3, and the light-emitting unit 2 is positioned inside the wall 5.

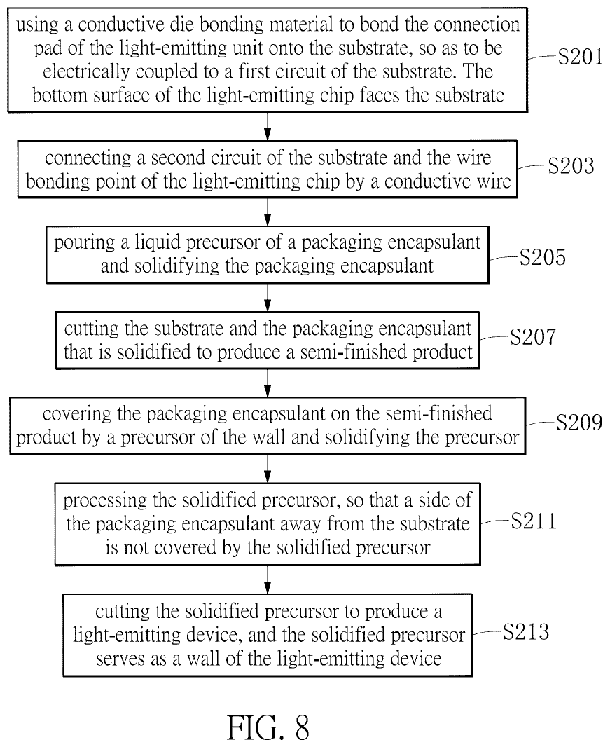

The above describes the structure of the light-emitting devices 100 and 100′ of the present disclosure. However, for a better understanding of the light-emitting device 100 of the present disclosure, the following introduces the manufacturing process of the light-emitting device 100′ with the wall 5 in one embodiment. The manufacturing method for the light-emitting device 100′ includes steps S201 to S213 (as shown in FIG. 8).

### Manufacturing Method of the Light-Emitting Device 100′

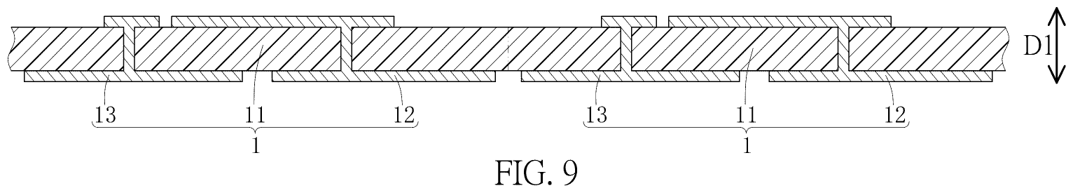

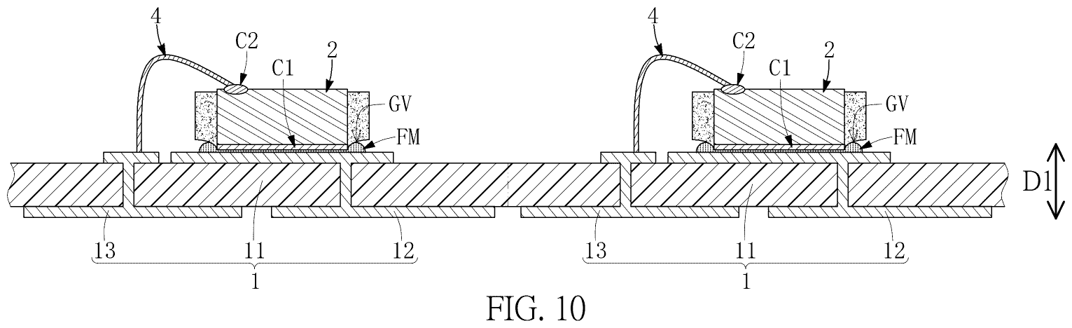

Steps S201 to S203 should be referred to in conjunction with FIG. 9 and FIG. 10.

The step S201 is implemented by using a conductive die bonding material FM to bond the connection pad C1 of the light-emitting unit 2 onto the substrate 1, so as to be electrically coupled to a first circuit 12 of the substrate 1 (as shown in FIG. 9 and FIG. 10). The bottom surface M2 of the light-emitting chip 21 faces the substrate 1.

The step S203 is implemented by connecting a second circuit 13 of the substrate 1 and the wire bonding point of the light-emitting chip by a conductive wire 4.

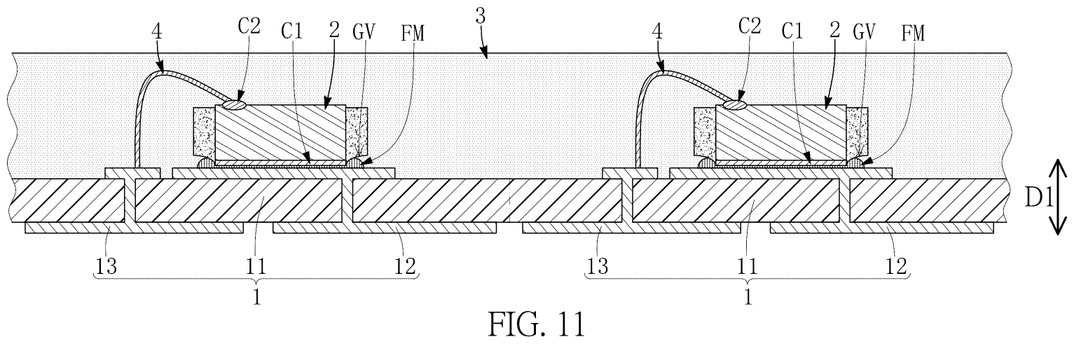

The step S205 is implemented by pouring a liquid precursor of a packaging encapsulant 3 and solidifying the packaging encapsulant 3 (as shown in FIG. 11). The light-emitting chip 21, the optical encapsulant 22, and the conductive wire 4 are covered by the packaging encapsulant 3 that is solidified.

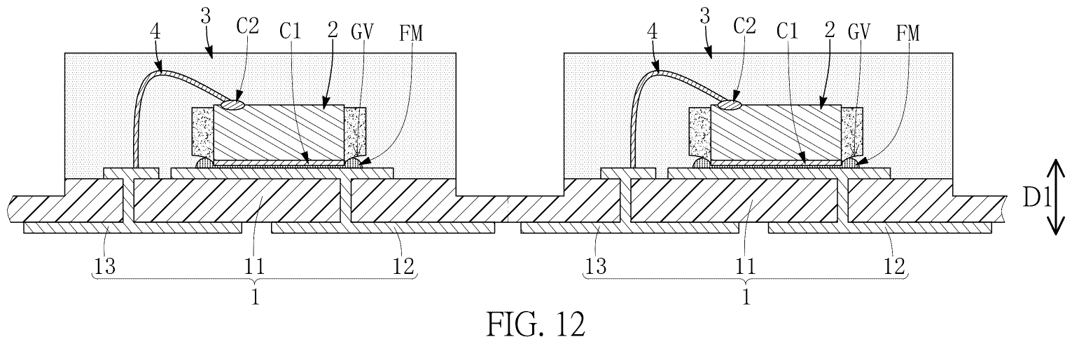

The step S207 is implemented by cutting the substrate 1 and the packaging encapsulant 3 that is solidified (as shown in FIG. 12) to produce a semi-finished product. When the product does not require the wall 5, the substrate 1 and the packaging encapsulant 3 that is solidified can be completely cut through. When the product requires the wall 5, perform a partial cut and proceed with subsequent steps. For example, as shown in FIG. 12, the cutting depth penetrates through the packaging encapsulant 3 and partially cuts into the substrate 1.

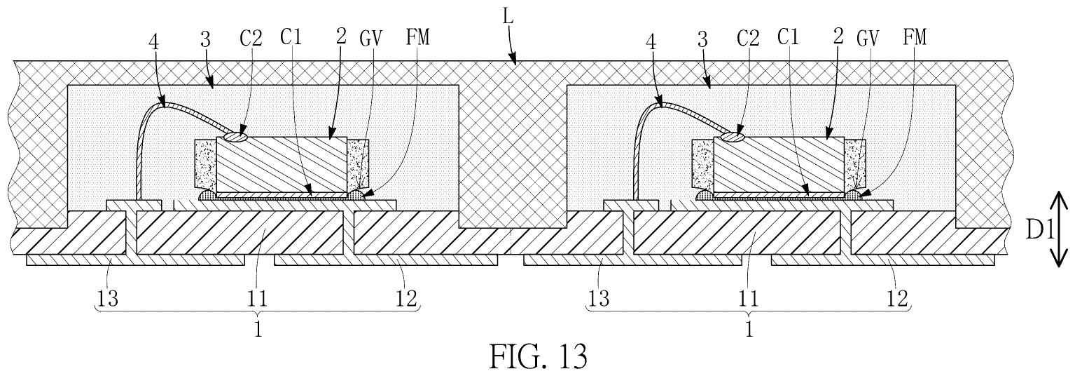

The step S209 is implemented by covering the packaging encapsulant 3 on the semi-finished product by a precursor of the wall 5 and solidifying the precursor (as shown in FIG. 13).

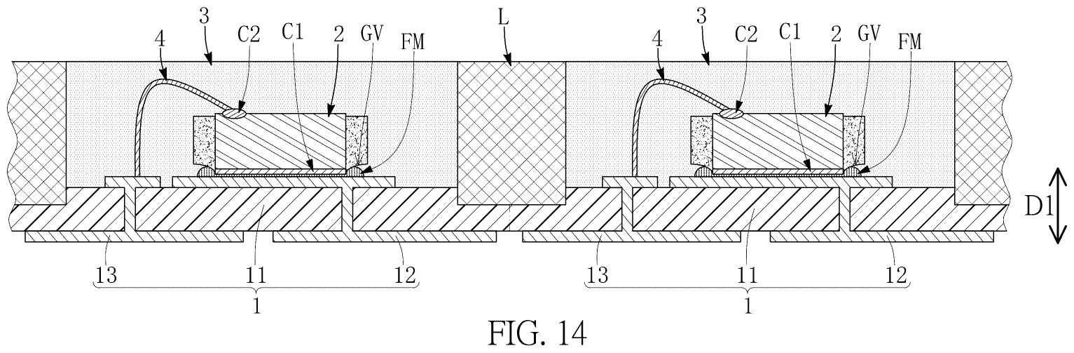

The step S211 is implemented by processing (e.g., polishing) the solidified precursor (as shown in FIG. 14), so that a side of the packaging encapsulant 3 away from the substrate 1 is not covered by the solidified precursor.

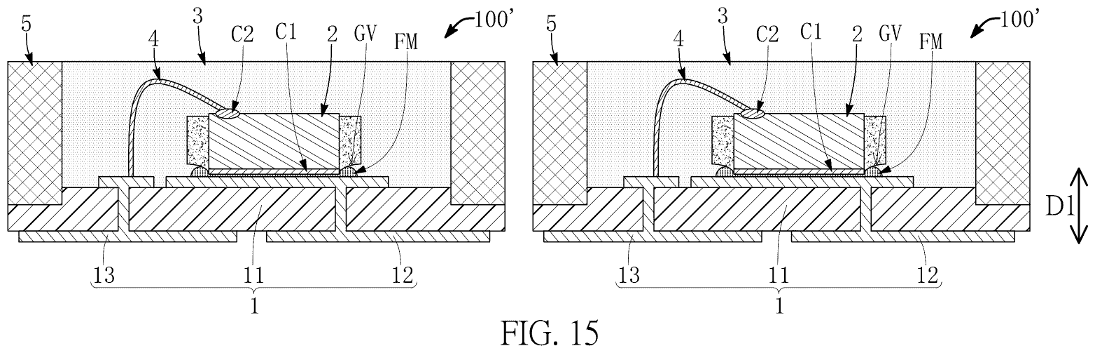

The step S213 is implemented by cutting the solidified precursor (and the substrate) to produce a light-emitting device 100′ (as shown in FIG. 15), and the solidified precursor serves as a wall 5 (e.g., a reflective wall) of the light-emitting device 100′.

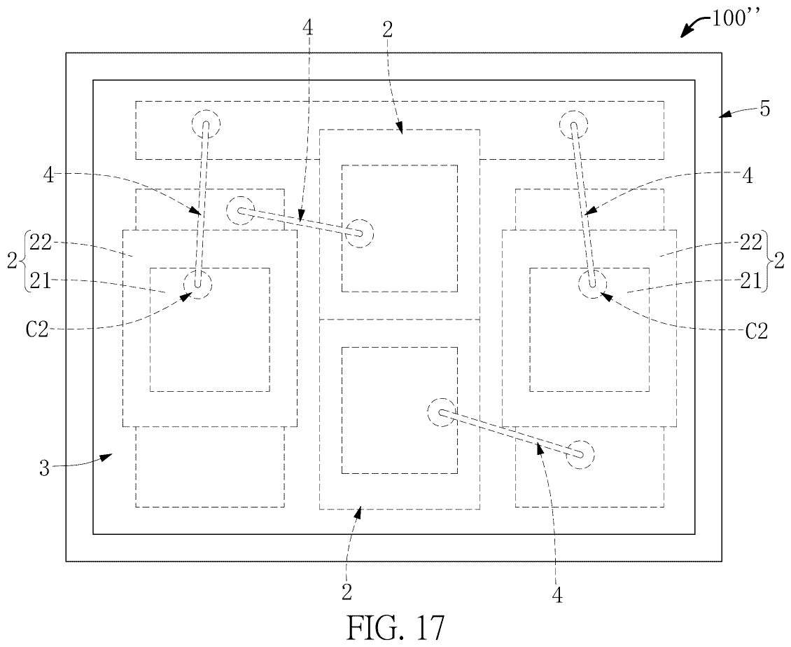

From the above content, it is clear that the light-emitting unit 2 of the present disclosure that is made into a CSP form on a vertical wafer not only achieves excellent yield and light output performance but also allows for more flexible configurations when applied to the light-emitting device. For example, as shown in FIG. 17, in the light-emitting device 100″ that is made into a CSP form on a vertical wafer, each of the vertical chips is surrounded by the optical encapsulant can individually control optical characteristics (e.g., light emission angle). Furthermore, the light-emitting units 2 can be freely combined, and CSPs of different colors can be integrated into a single light-emitting device. The design provides a high degree of flexibility and simplifies the manufacturing process of the light-emitting device, which cannot be achieved with conventional vertical chip processes.

### Beneficial Effects of the Embodiment

In conclusion, in the light-emitting unit and the light-emitting device. provided by the present disclosure, by virtue of “the surrounding side surface of the light-emitting chip being surrounded by the optical encapsulant, and the top surface and the bottom surface of the light-emitting chip being exposed outside of the optical encapsulant,” the light-emitting unit and light-emitting device can improve yield and light emission performance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-emitting unit, comprising:
a light-emitting chip having a top surface and a bottom surface opposite to each other in a thickness direction, and a surrounding side surface, wherein the top surface and the bottom surface are surrounded by the surrounding side surface, and the light-emitting chip includes a connection pad located on the bottom surface and a wire bonding point that is located on the top surface; and
an optical encapsulant, wherein the surrounding side surface of the light-emitting chip is surrounded by the optical encapsulant, and the top surface and the bottom surface of the light-emitting chip are exposed outside of the optical encapsulant.

2. The light-emitting unit according to claim 1, wherein a portion of the optical encapsulant adjacent to the connection pad has a groove.

3. The light-emitting unit according to claim 2, wherein a cross-section of the groove along the thickness direction is in a shape of two arcs.

4. The light-emitting unit according to claim 1, wherein the light-emitting chip has a first minimum thickness along the thickness direction, the optical encapsulant has a second minimum thickness along the thickness direction, and the first minimum thickness is greater than the second minimum thickness.

5. The light-emitting unit according to claim 4, wherein the second minimum thickness is within a range from 75% to 85% of the first minimum thickness.

6. The light-emitting unit according to claim 4, wherein the optical encapsulant includes a plurality of functional particles.

7. The light-emitting unit according to claim 6, wherein the functional particles include at least one of light-reflecting particles, coloring particles, light-diffusing particles, light-absorbing particles, and fluorescent particles.

8. The light-emitting unit according to claim 1, wherein the top surface of the light-emitting chip has a first height position, the optical encapsulant includes a platform surface having a second height position, and the second height position is lower than the first height position, so that a portion of the surrounding side surface adjacent to the top surface is exposed outside of the optical encapsulant.

9. The light-emitting unit according to claim 8, wherein a height difference between the first height position and the second height position is less than 50% of a thickness of the light-emitting chip along the thickness direction.

10. The light-emitting unit according to claim 9, wherein the height difference is within a range from 10 micrometers to 15 micrometers.

11. The light-emitting unit according to claim 8, wherein a width of the platform surface is greater than or equal to 30 micrometers.

12. A light-emitting device including the light-emitting unit as claimed in claim 1, comprising:
a substrate including a first circuit and a second circuit, wherein the light-emitting unit is disposed on the substrate; and
a packaging encapsulant disposed on the substrate, wherein the light-emitting unit is covered by the packaging encapsulant;
wherein the light-emitting chip is die-bonded to the first circuit through the connection pad, the wire bonding point is connected to the second circuit through a conductive wire of the light-emitting device, and the conductive wire is exposed outside of the optical encapsulant.

13. The light-emitting device according to claim 12, wherein the light-emitting device further includes a wall, wherein the packaging encapsulant is surrounded by the wall.

14. The light-emitting device according to claim 12, wherein a portion of the optical encapsulant adjacent to the connection pad has a groove, and the groove is filled with the packaging encapsulant.

15. The light-emitting device according to claim 12, further comprising a plurality of the light-emitting units.
